(19) United States
(12) Patent Application Publication
(10) Pub. No.: US 2010/0018566 A1
(43) Pub. Date: Jan. 28, 2010

(54) APPARATUS AND METHOD FOR LEVITATING A PORTABLE SOLAR ARRAY

(76) Inventor: Orin Jackson, Hauula, HI (US)

Correspondence Address: Steven L. Rinehart, 1059 E. Millstream Way, Bountiful, UT, 84010, US

(21) Appl. No.: 12/179,567

(22) Filed: Jul. 24, 2008

(51) Int. Cl. H01L 31/042; F24J 2/38; B64B 1/50

(52) U.S. Cl. 136/246; 126/572; 244/33

(57) ABSTRACT

An apparatus and method are disclosed for levitating photovoltaic arrays, or solar energy panels, above ground level using balloons affixed to the solar energy panels. The apparatus includes batteries and other modules necessary to serve a variety of needs and may optionally be stowed and/or portable.

### FIELD OF THE INVENTION

This invention relates to photovoltaics and more particularly relates to portable solar energy panels levitated on tubular balloons.

### BACKGROUND

### Description of the Related Art

The photovoltaic generation of electricity is usually accomplished using interconnected assemblies of photovoltaic cells. Multiple photovoltaic cells are often combined and known as photovoltaic arrays or solar energy panels. In general, photovoltaic arrays, or solar energy panels, are fixed to the ground, or heavy objects such as buildings (known as building integrated photovoltaics (BIPV)), as well as cars, farm equipment, greenhouses, and the like. The solar energy panels are often configured to direct electrical current to charge converters, power inverters, and batteries of various kinds, including wet-cell lead acid batteries, absorbed glass mat (AGM) batteries, nickel-cadmium, and lithium-ion. The apparatus comprising the solar energy panels and its accompanying converters, inverters and batteries is referred to by those of skill in the art as a photovoltaic system.

Solar energy panels may be rigid or flexible. Flexible thin solar modules, or nano thin solar panels, have been developed in recent years which are significantly lighter than traditional solar energy panels which usually comprise plastic solar cells. Nano thin solar panels are formed by depositing a photoactive layer over a flexible substrate, such as solar-absorbing “nano-ink,” or inorganic nano-crystals

Optimal performance from any solar energy panel is achieved when the face of the solar panel is perpendicular to the direction of travel of the light hitting the solar panel, usually sunlight. Photons in the sunlight excite electrons in zero biased photodiodes within the solar energy panels. This process transduces the desired electrical current in the photovoltaic system; however, this process also causes the solar energy panel to heat up resulting in a consequential degradation in performance. For this reason solar thermal collectors are often mounted behind solar energy panels to cool them, and keep the solar energy panels operating efficiently in lower temperature conditions.

Because the effectiveness of solar panels also increases with their size, solar panels must often be very large to serve their intended applications. Large solar panels can prove very cumbersome to position and manage, particularly when stowed then configured for temporary uses in close quarters such as campsites. The solar energy panels may take space needed for other purposes. People and other objects at ground level can block sunlight necessary to transduce electricity in the solar panels. Furthermore, it can also be difficult for human operators to adjust solar panels as the sun's position relative to the solar panels changes throughout the day.

### SUMMARY

From the foregoing discussion, it should be apparent that a need exists for an apparatus and method to levitate a portable solar array. Beneficially, such an apparatus and method would levitate the solar array above people and other objects that might obstruct it from sunlight.

The present invention has been developed in response to the present state of the art, and in particular, in response to the problems and needs in the art that have not yet been fully solved by currently available photovoltaic systems. Accordingly, the present invention has been developed to provide an apparatus and method for levitating a solar array that overcome many or all of the above-discussed shortcomings in the art.

The apparatus which transduces an electrical current photovoltaicly is provided with a plurality of modules configured to impart the necessary functionality to levitate a functional solar array. These modules in the described embodiments include one or more balloons comprising a lighter than air gas; one or more solar energy panels suspended above a ground surface, the one or more solar energy panels affixed to the one or more balloons; one or more tethers coupled at a first end to one of the one or more balloons and the one or more solar energy panels, the one more tethers coupled at a second end to one of a ground surface and a weighted device; a charge controller for regulating direct electrical current from the one or more solar energy panels to a battery system; and a battery system for storing electricity.

In one embodiment of the apparatus, the weighted device further includes a tether control module configured to automatically position the one or more solar energy panels to face incoming sunlight such that the planar surface of the one or more solar energy panels in perpendicular to the sunlight's direction of travel. In some embodiments the tether control module is adjustable by a human operator.

In further embodiments of the apparatus, the one or more solar energy panels comprise nano thin solar panels. In still further embodiments, the solar energy panels are mounted to a frame comprising evacuated tubing affixed to the edges of the one or more solar energy panels, the evacuating tubing comprising the one or more mylar balloons.

The apparatus may also include a solar thermal collector for one or more of cooling the one or more solar energy panels to improve performance and heating a liquid. The apparatus may also be portable.

A method of the present invention is also presented for transducing an electrical current photovoltaicly. The method in the disclosed embodiments substantially includes the steps necessary to carry out the functions presented above with respect to the operation of the described apparatus and system. In one embodiment, the method includes affixing one or more balloons comprising a lighter than air gas to one or more solar energy panels; suspending the solar energy panels above a ground surface; coupling one or more tethers at a first end to one of the one or more balloons and the one or more solar energy panels; coupling the one more tethers coupled at a second end to one of a ground surface and a weighted device; and storing electricity in a battery system.

The method may further comprise a step of automatically positioning the one or more solar energy panels to face incoming sunlight such that the planar surface of the one or more solar energy panels in perpendicular to the sunlight's direction of travel.

The method may also comprise cooling the one or more solar energy panels using a solar thermal collector to improve performance of the one or more solar energy panels.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention may be practiced without one or more of the specific features or advantages of a particular embodiment. In other instances, additional features and advantages may be recognized in certain embodiments that may not be present in all embodiments of the invention.

These features and advantages of the present invention will become more fully apparent from the following description and appended claims, or may be learned by the practice of the invention as set forth hereinafter.

### BRIEF DESCRIPTION OF THE DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1 illustrates a typical, prior-art photovoltaic system;

FIG. 2 is a stylized view of one embodiment of the solar energy panels in accordance with the present invention;

FIG. 3 is an alternative stylized portion of a photovoltaic system in accordance with the present invention;

FIG. 3B is an alternative stylized view of a photovoltaic system in different configurations in accordance with the present invention;

FIG. 3C is an alternative stylized view of a photovoltaic system in accordance with the present invention; and

FIG. 4 is a flow diagram of one embodiment of the steps of a method in accordance with the present invention.

### DETAILED DESCRIPTION

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art will recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

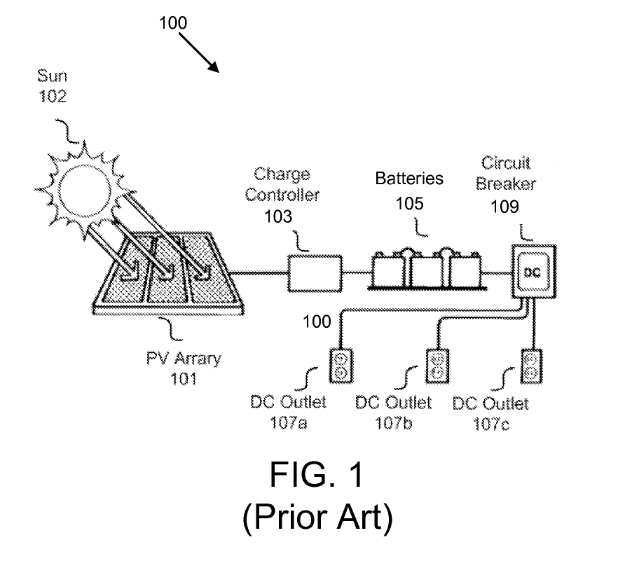

FIG. 1 illustrates a typical, prior-art photovoltaic system 100. FIG. 1 includes a photovoltaic (PV) array 101, a charge controller 103, batteries 105, direct current (DC) outlets 107a-c, and a circuit breaker 109.

The PV array 101 direct electrical current to the charge controller 103. The PV array 101 comprises solar energy cells, or photodiodes, that may be rigid or flexible. The PV array 101 may comprise flexible thin solar modules, or nano thin solar panels, which may comprise solar-absorbing “nano-ink,” or inorganic nano-crystals. The PV array 101 is activated by light such as light from a sun 102. The protons in the sunlight transduce an electrical current in the system 100 by exciting electrons within the PV array 101.

The charge controller 103 regulates DC current from the PV array 101 to the batteries 109. The charge controller 103 may control the amount and rate of electrical current committed to, or drawn from, the batteries 105. The charge controller 103 may prevent overcharging, which can reduce battery performance and battery lifespan.

The batteries 105 are well-known to those of skill in the art. In the prior art, they are rechargeable and may include wet-cell lead acid batteries, absorbed glass mat (AGM) batteries, nickel-cadmium batteries, and lithium-ion batteries.

The circuit breaker 109 is well-known to those of skill in the art. The circuit breaker 103 is an automatically-operated electrical switch that protects the system 100 from damage caused by an overload or a short-circuit.

The DC outlets 107a-c are well known in the art, and include a live wire, a neutral wire, and an optional ground wire. The DC outlets 107a-c usually comprise power plugs made of steel, iron, brass, zinc, tin or nickel, but may also comprise power sockets.

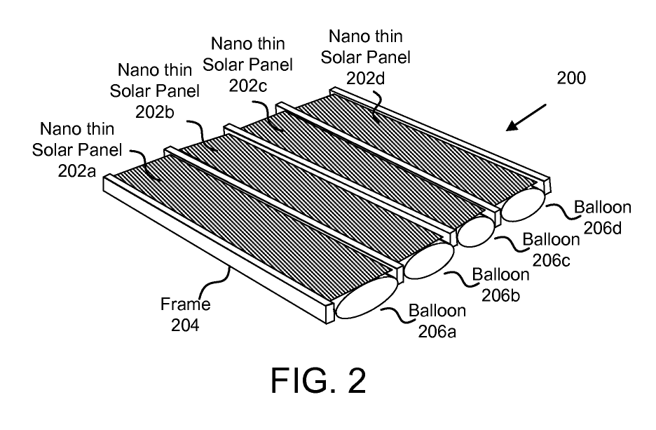

FIG. 2 is a stylized view of one embodiment of the solar energy panels in accordance with the present invention. The apparatus 200 shown in FIG. 2 includes nano thin solar panels 202a-d, a frame 204, and balloons 206a-d.

The nano thin solar panels 202a-d are substantially described above. In the shown embodiment the nano thin solar panels 202a-d comprise a photoactive layer deposited over a flexible substrate; but, in some embodiments of the present invention, the photoactive layer may be deposited over the frame 204 itself. In other embodiments, the photovoltaic layer is deposited over a rigid substrate which serves as the frame 204. In still other embodiments, the nano thin solar panels 202a-d may comprise heavier, more traditional solar energy panels.

In certain embodiments of the present invention, the nano thin solar panels 202a-d may be convex, concave, spherical or flat.

The frame 204 comprises any structural system that supports the other components in the apparatus 200. In the shown embodiment, the frame 204 comprises aluminum bars to which the nano thin solar panels 202a-d and the balloons 206a-d are affixed. In the preferred embodiment, the frame 204 is rigid, but in other embodiments it is flexible. The frame 204 may be portable, or modularized for assembly by a human manager.

In the shown embodiment, the balloons 206a-d comprise mylar tubes fillable with a lighter than air gas, such as hydrogen, helium, nitrous oxygen, or even heated air. The balloons 206a-d are affixed to the frame 204 and/or the nano thin solar panels 202a-d. The balloons 206a-d may be tubular and formed to fit within evacuated portions of the frame, formed to follow the edges of the frame 204 or nano thin solar panels 202a-d, or otherwise formed in a predetermined manner. The balloons may be made of any material as well-known to those of skill in the art. In the preferred embodiment, the balloons 206a-d are tubular, and fitted behind the nano thin solar panels 202a-d.

The balloons 206a-d maybe affixed under, over, or adjacent to the frame 204 and/or nano thin solar panels 202a-d. The balloons 206a-d may be reusable or disposable. The balloons 206a-d levitate, or suspend, the nano thin solar panels 202a-d above a ground surface by displacing a quantity of air whose weight exceeds that of the apparatus 200 at ground level.

Certain embodiments of the apparatus 200 may include a solar thermal collector affixed to the nano thin solar panels 202a-d (not shown). The solar thermal collector may serve the dual purpose of cooling the nano thin solar panels 202a-d and of heating a fluid used in the solar thermal collector for another purpose, such as showering, cooking, climate control, and the like. The fluid may comprise water, oil, antifreeze or the like. In yet another embodiment of the present invention, the solar thermal collector heats air filling the balloons 206a-d and thus keep the apparatus 200 suspended, or levitated, above a ground surface.

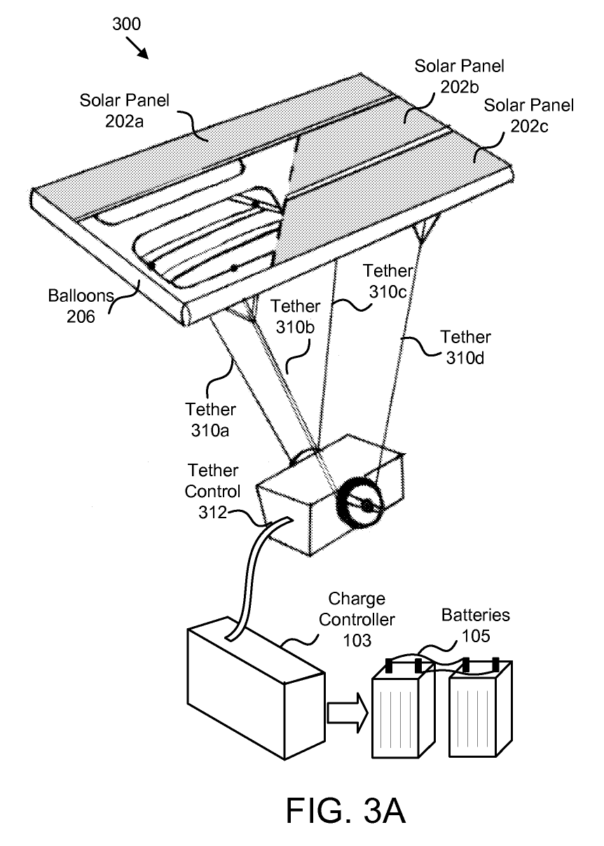

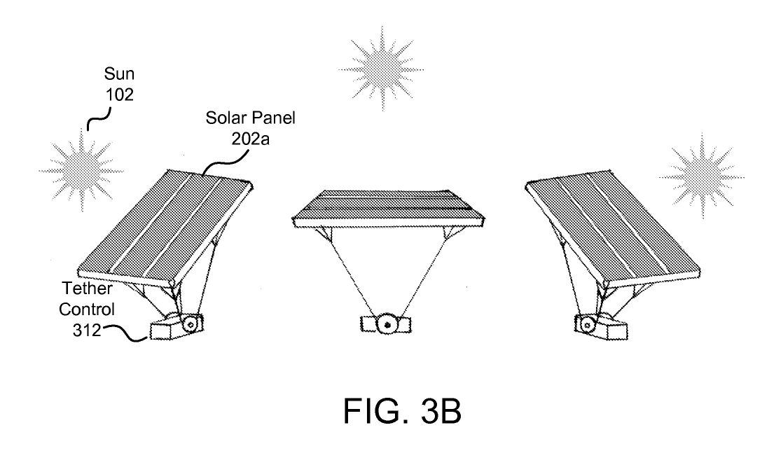

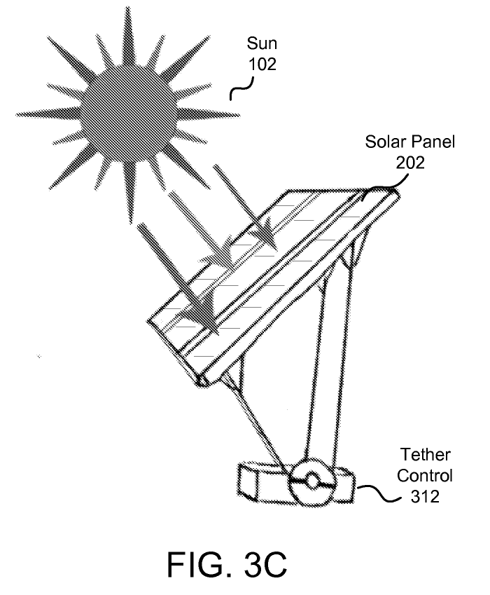

FIG. 3 is an alternative stylized portion of a photovoltaic system in accordance with the present invention. The apparatus 300 substantially includes the embodiments and modules described above with regard to the apparatus and system depicted in FIGS. 1-2. The apparatus 300 includes solar panels 202a-c, balloons 206, tethers 310a-d, a tether control module 312, a charge controller 103, and batteries 105.

The solar panels 202a-c are substantially described above well-known to those of skill in the art. The solar panels 202a-c in the shown embodiment comprise flexible, nano thin solar energy panels. The solar panels 202a-c are supported by the balloons 206. In some embodiments, the entire undersurface of the solar panels 202a-b may be blanketed with multiple rows of balloons 206.

The balloons 206 in the shown embodiment comprise a plurality of balloons substantially described above in relation to FIG. 2. In some embodiments, the balloons 206 may comprise a single balloon affixed to the solar panels 202a-c and formed to fit the solar panels 202a-b.

The tethers 310a-d anchor the levitated apparatus 200 to a stationary, weighted device. In the shown embodiment, the weighted device comprises the tether control module 312. The tethers 310a-d are attached at a first end to the balloons 206 and attached at a second end to the tether control module 312. The tethers may be flexible or rigid, and may comprise rope, cord, chain, wire, bars, high voltage high temperature wire, or the like.

The tether control module 312, in the shown embodiment, automatically adjusts the length of the tethers 310a-d to position the surface of the solar panels 202a-b at a roughly perpendicular angle to direction of travel of incoming light. Optimal performance for the solar panels 202a-c is achieved when the face of the solar panels 202a-b is perpendicular to the direction of travel of the light hitting the solar panels 202a-c. The tether control module 312 may comprise an optical sensor, or multiple optical sensors, that measure the physical position and/or intensity of the sun 102 relative to the solar panels 202a-c. In other embodiments, the solar panels 202a-c comprise the optical sensor(s) and relay information down the tether 3 10a-d to the tether control module 312.

In some embodiments, the tether control module 312 is adjustable by a human operator, or external client, which adjusts the length of the tethers 310a-d to position the solar panels 202a-c at a perpendicular angle to incoming sunlight. In some embodiments, the tether control module may be levitated above ground level with the solar panels 202a-c.

The charge controller 103 is substantially described above.

The batteries 105 are substantially described above, and may be connected in series or in parallel.

The apparatus 300 may be optionally stowable and/or portable. Some embodiments of the present invention may also include DC outlets 107a-c, a power inverter, and one or more alternating current (AC) outlets.

FIG. 3B is an alternative stylized view of a photovoltaic system in different configurations in accordance with the present invention. The apparatus 300 in FIG. 3B substantially includes the embodiments and modules described above with regard to the apparatus and system depicted in FIGS. 1-3A.

The sun 102 transduces an electric current in the solar panel 202. The tether control module 312 adjusts the spatial orientation of the solar panel 202 such that it faces the sun 102 as the sun travels relative to the solar panel 202.

FIG. 3C is an alternative stylized view of a photovoltaic system in accordance with the present invention. The apparatus 300 in FIG. 3C substantially includes the embodiments and modules described above with regard to the apparatus and system depicted in FIGS. 1-3B.

The sun 102 transduces an electric current in the solar panel 202. The tether control module 312 adjusts the spatial orientation of the solar panel 202 such that it faces the sun 102 as the sun travels relative to the solar panel 202.

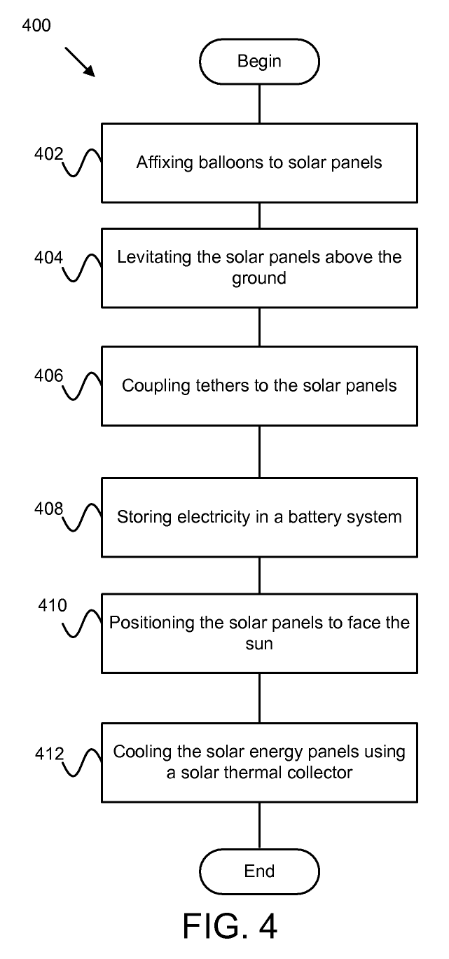

FIG. 4 is a flow diagram of one embodiment of the steps of the method in accordance with the present invention. The method 400 substantially includes the embodiments and modules described above with regard to the apparatus and system depicted in FIGS. 1-3. The method 400 begins and balloons 206 are affixed 402 to solar panels 202. In some embodiments, the balloons 206 are affixed to a frame 204.

The method 400 continues and the solar panels 202 are levitated, or suspended, 404 above ground level. This levitation takes place in response to the balloons 206 being filled with a lighter than air gas.

The method 400 continues by coupling 406 tethers 310 to the solar panels 202. The coupling 406 and levitating 404 steps are not necessarily sequential, and may occur in any order or simultaneously.

Next, the method 400 continues to the storing 408 step when electricity is stored in a battery system 105.

The method 400 continues by positioning 410 the solar panels 202 to face the sun for optimal performance.

Finally, in the shown embodiment, the solar panels 202 are cooled 412 by a solar thermal collector, and the method 400 ends.

Other embodiments of the method 400 may comprise using the stored electricity, automatically positioning the solar panels, and/or automatically levitating the solar panels. None of the steps of the method 400 are necessarily sequential.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus to transduce an electrical current photovoltaicly, the apparatus: comprising:
one or more balloons comprising a lighter than air gas;
one or more solar energy panels levitated above a ground surface, the one or more solar energy panels affixed to the one or more balloons;
one or more tethers coupled at a first end to one of the one or more balloons and the one or more solar energy panels, the one more tethers coupled at a second end to one of a ground surface and a weighted device;
a charge controller for regulating direct electrical current from the one or more solar energy panels to a battery system; and
a battery system for storing electricity.

2. The apparatus of claim 1, wherein the weighted device comprises a tether control module configured to automatically position the one or more solar energy panels to face incoming sunlight such that the planar surface of the one or more solar energy panels in perpendicular to the sunlight's direction of travel.

3. The apparatus of claim 2, wherein the tether control module is adjustable by a human operator.

4. The apparatus of claim 1, wherein the one or more solar energy panels comprise nano thin solar panels.

5. The apparatus of claim 1, wherein the one or more solar energy panels are mounted to a frame comprising evacuated tubing affixed to the edges of the one or more solar energy panels, the evacuating tubing comprising the one or more balloons.

6. The apparatus of claim 1, further comprising a solar thermal collector for one or more of cooling the one or more solar energy panels to improve performance and heating a liquid.

7. The apparatus of claim 6, wherein the solar thermal collector heats air in the one or more balloons levitating the solar energy panels.

8. The apparatus of claim 1, wherein the apparatus is portable.

9. A method of transducing an electrical current photovoltaicly, the steps of the method comprising:
affixing one or more balloons comprising a lighter than air gas to one or more solar energy panels;
levitating the solar energy panels above a ground surface;
coupling one or more tethers at a first end to one of the one or more balloons and the one or more solar energy panels;
coupling the one more tethers coupled at a second end to one of a ground surface and a weighted device; and
storing electricity in a battery system.

10. The method of claim 9, further comprising automatically positioning the one or more solar energy panels to face incoming sunlight such that the planar surface of the one or more solar energy panels in perpendicular to the sunlight's direction of travel.

11. The method of claim 9, further comprising cooling the one or more solar energy panels using a solar thermal collector to improve performance of the one or more solar energy panels.
